(19) United States
(12) Patent Application Publication
(10) Pub. No.: US 2003/0185315 A1
(43) Pub. Date: Oct. 2, 2003

(54) Frequency analyzer

(76) Inventor: Tzong-Kwei Chen, Hsinchu (TW)

Correspondence Address: DELLETT AND WALTERS, 310 S.W. FOURTH AVENUE, SUITE 1101, PORTLAND, OR, 97204, US

(21) Appl. No.: 10/264,103

(22) Filed: Oct. 2, 2002

(30) Foreign Application Priority Data
Mar. 29, 2002 (TW) 091106349

(51) Int. Cl. G06F 19/00; G01R 23/00; H04L 27/06

(52) U.S. Cl. 375/316

(57) ABSTRACT

A frequency analyzer uses a new approach to determine simple and multi-frequency components. The invention mainly comprises a complex filter and a frequency discriminator. The real number part of the input frequency can be represented by a frequency spectrum composed of both positive frequencies and negative frequencies. The complex filter receives an input signal through two sampling points, and then the frequency discriminator computes the phase difference between two sampled signals from these two consecutive sampling points. After applying an inverse trigonometric function, the demodulated frequency is derived from the phase difference. Using a complex function to derive the demodulated frequency is more advantageous in that many high-frequency sampling circuits become unnecessary, thus reducing the power consumption of the frequency demodulation circuit.

### BACKGROUND OF THE INVENTION

1. Field of the Invention

The present invention relates to a frequency analyzer using a new approach to determine a simple frequency and multi-frequency signals, in particular, to a new detection technique that uses a complex function to compute the phase difference from two sampled signals, and applies an inverse trigonometric function to the phase difference to derive the demodulated frequency.

2. Description of Related Art

Tone detection is often used in telecommunications. Caller-ID or the display of the caller's phone number on a recipient's mobile phone is one of its many applications. Conventional signaling techniques often employed in telecommunications are Frequency Shift Keying (FSK), Dual Tone Multi-Frequency (DTMF) and Channel Associated Signaling (CAS).

With reference to FIG. 9, the process of tone detection constitutes first passing an input signal through a bandpass filter to block signals and noise outside a specific frequency range. The input signal is then fed into a comparator to be compared with a threshold value, and is then converted to digital format. The digital signal is then sent through a frequency counter to obtain the actual demodulated frequency. For a reasonably accurate frequency value, for example, an error rate below one percent, the operation frequency of the frequency counter has to be 200 times the input frequency, or even higher.

Yet to meet the extremely high frequency requirement for signal sampling, the circuit design becomes much more complicated, and the operating specifications of circuit components also have to match the high standards. However, the result is more power for the control circuit and relatively high component costs due to the use of a critical component, the bandpass filter. Replacements with other semiconductor circuits are not available.

In view of the weaknesses in conventional tone detection techniques, the present invention provides a new frequency analyzer that can determine single and multi-frequency components with high efficiency and reduced power. To implement the new approach in frequency demodulation only requires a sampling apparatus that can operate at a sampling rate four times the input frequency to determine the specific single or multi-frequency signals.

### SUMMARY OF THE INVENTION

The main objective the present invention is to provide a frequency analyzer using a new approach to determine single and multi-frequency signals with peak efficiency and minimized power.

The second objective of the present invention is to provide an apparatus for detection of single frequency/multi-frequency signals, wherein a complex filter receives two consecutively sampled signals from two sampling points, and a frequency discriminator then uses a complex function to extrapolate the phase difference from the two sampled signals. When applied to a given inverse trigonometric function, the actual demodulated frequency can be derived from the phase difference. Since the frequency computation is largely performed with digital processing without using any high frequency counters, the power requirements for the circuit can be significantly reduced.

The third objective of the present invention is to provide a frequency analyzer that employs a complex function to compute the demodulated frequency, which greatly reduces the complexity of the circuit design and the related manufacturing costs associated with the introduction of new semiconductor technology.

The fourth objective of the invention is to provide a frequency analyzer that can employ low-frequency logic circuits for frequency computation.

The frequency analyzer in accordance with the present invention is mainly composed of a complex filter and a frequency discriminator.

The complex filter is used to filter out the harmonic frequency components, while keeping either the positive or negative frequency component for frequency computation, depending on the choice.

The frequency discriminator, having received the two sampled signals output from the complex filter, uses a complex function to extrapolate the phase difference from the two consecutive sampled signals. The discriminator then applies an inverse trigonometric function to the phase difference to derive the actual demodulated frequency.

Other advantages and features of the invention will become apparent from the detailed description when taken in conjunction with the attached drawings.

### BRIEF DESCRIPTION OF THE DRAWINGS

FIG. 1 is the frequency spectrum of a cosine function for positive frequency components in the frequency domain.

FIG. 2 is a block diagram of the first embodiment of the frequency analyzer in accordance with the present invention;

FIG. 3 is a diagram of the transfer characteristics of a low-pass filter;

FIG. 4 is a diagram of the transfer characteristics of a complex filter;

FIG. 5 is a schematic diagram of the transformation process in the complex filter in FIG. 2;

FIG. 6 is a diagram of frequency sampling points with different phase angles represented in vector form on a complex plane;

FIG. 7 is a block diagram of the second embodiment of the frequency analyzer in accordance with the present invention;

FIG. 8 is a block diagram of the third embodiment of the frequency analyzer in accordance with the present invention;

FIG. 9 is a block diagram of a conventional frequency analyzer.

### DETAILED DESCRIPTION OF THE CURRENT EMBODIMENT

According to the principle of Fourier transforms, a continuous periodic wave can be expressed in the form of the summation of a series of sinusoidal components. Alternatively, the series can be charted by frequency spectrum. The Fourier series of a periodic waveform can be expressed in the frequency domain by symmetric frequency line spectrum. For example

$$cos {ω}_{o} t = \frac{{ⅇ}^{j {ω}_{o} t} + {ⅇ}^{- j {ω}_{o} t}}{2} \qquad ( 1 )$$

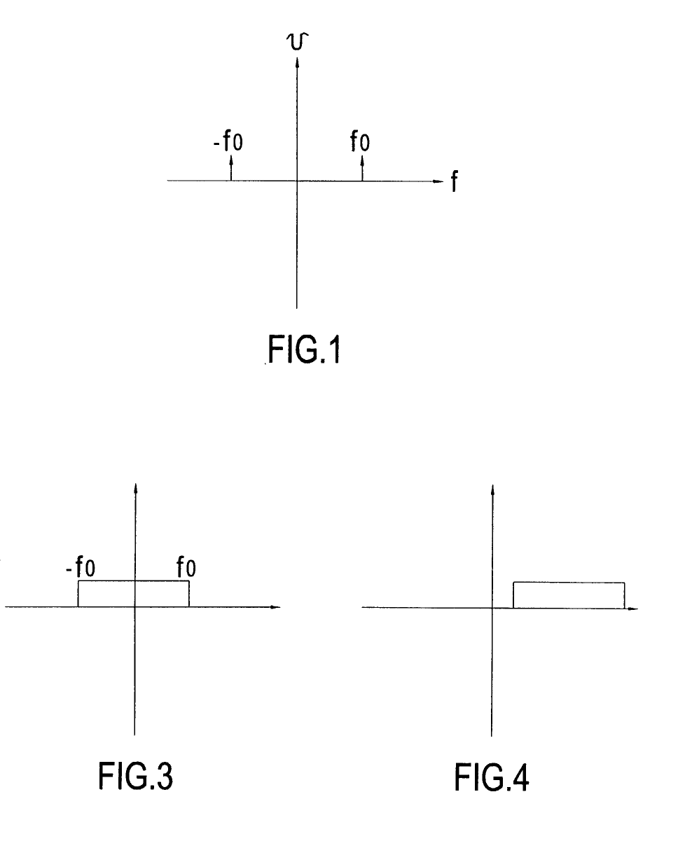

The frequency spectrum of a sinusoidal wave contains both positive frequency (f₀) and negative frequency (−f₀) components in the frequency domain as shown in FIG. 1. Either one can be used for frequency computation depending on the choice, but in the current embodiment only the positive frequency component is used for illustration, specifically the e^{jω}^{ₒ}^{t} part. According to the complex function, the complex form of the expression e^{jω}^{ₒ}^{t}=cos ωₒt+j sin ωₒt is composed of the real part that is the first part, and the imaginary part that is the second part. In the following description of the current embodiment, the real part of the input signal is represented by the notation I, and the imaginary part by Q.

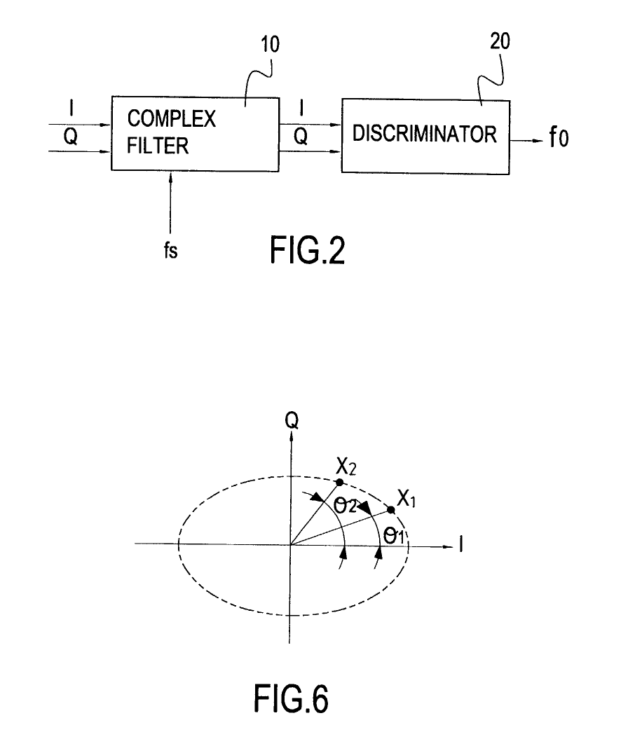

With reference to FIG. 2, the frequency analyzer comprises a complex filter (10) and a frequency discriminator (20) coupled to the complex filter (10). The input of the complex filter (10) receives modulated signals that can be expressed in complex form for sampling. The complex filter (10) extracts either the positive or negative frequency component from the input signal.

The complex filter (10) is a modified low-pass filter. With reference to FIG. 3, the transfer characteristics of a standard low-pass filter cover both the positive and negative frequencies. When the signal values output from the filter are shifted to the right as shown in FIG. 4, only the positive frequencies still remain, which are employed by the frequency analyzer.

The transfer function for the low-pass filter can be expressed as

$$H ( z ) = \frac{1 + {z}^{- 1}}{1 + {z}^{- 2}} ,$$

wherein z=e^{(jω)}; and if z is replaced by z×e^{(-jω0)}, the transfer function for the complex filter (10) becomes (as shown in FIG. 4):

$${H}_{C} ( z ) = \frac{1 + {( z \times {ⅇ}^{- j ω0} )}^{- 1}}{1 + {( z \times {ⅇ}^{- j ω 0} )}^{- 2}} = \frac{1 + {ⅇ}^{j ω 0} \times {z}^{- 1}}{1 + {ⅇ}^{ j 2 ω 0} \times {z}^{- 2}} \qquad ( 2 )$$

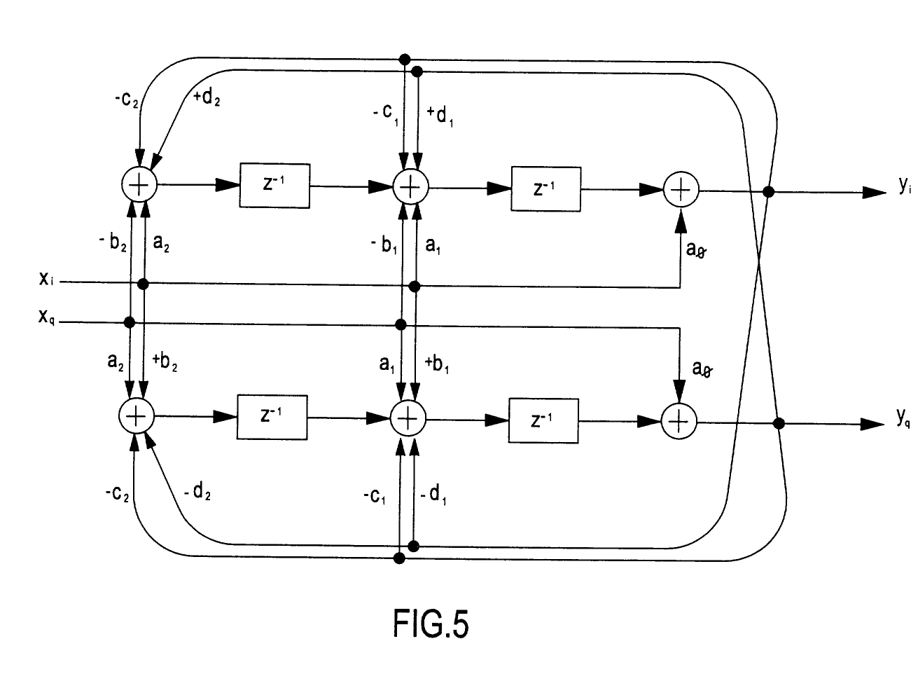

Based on the transformation process in the complex filter (10) as shown in FIG. 5, the transfer function can be revised to become:

$$H ( z ) ≡ \frac{Y ( z )}{X ( z )} = \frac{{a}_{0} + ( {a}_{1} + {b}_{1} j ) {z}^{- 1} + ( {a}_{2} + {b}_{2} j ) {z}^{- 2}}{1 + ( {c}_{1} + {d}_{1} j ) {z}^{- 1} + ( {c}_{2} + {d}_{2} j ) {z}^{- 2}} \qquad ( 3 )$$

and after cross multiplication of the factors on opposite sides of the equation, the equation becomes:

y(n)+(c₁+d₁j)y(n−1)+(c₂+d₂j)y(n−2)=a₀x(n)+(a₁+b₁j)x(n−1)+(a₂+b₂j)x(n−2)

and after rearranging the terms, the expression for y(n) becomes:

y(n)=a₀x(n)+a₁x(n−1)+a₂x(n−2)−c₁y(n−1)−c₂y(n−2)+j[b₁x(n−1)+b₂x(n−2)−d₁y(n−1)−d₂y(n−2)]=yᵢ+jy_{q} (4)

Therefore, the positive frequency portion of an input modulated frequency can be obtained.

The positive frequencies are then sampled again with a sampling frequency indicated by (fₛ). The frequency discriminator (20) then computes the demodulated frequency based on the phase difference. The sampling frequency has to match the Nyquist sampling rate, which means the rate should at least double the maximum frequency of the sample. When expressed in vector form on a complex plane, as shown in FIG. 6, x₁ and x₂ represent two consecutively sampled signals with the phase angles respectively represented by the arguments θ₁ and θ₂, wherein:

x₁=A₁·e^{j}^{^{θ}}¹=a₁+jb₁ (5)

x₂=A₂·e^{j}^{^{θ}}²=a₂+jb₂ (6)

If taking x₁ of the complex conjugate x₁*=a₁−jb₁ and multiply with x₂, that is:

x₂×x₁*=A₁·A₂·e^{j(θ}^{₂}^{-θ}^{₁}⁾=(a₁·a₂+b₁·b₂)+j(a₁·b₂−a₂·b₁) (7)

The phase difference between the two arguments becomes

$$\begin{matrix}Δ θ = {θ}_{2} - {θ}_{1} = {tan}^{- 1} ( \frac{{a}_{1} \cdot {b}_{2} - {a}_{2} \cdot {b}_{1}}{{a}_{1} \cdot {a}_{2} + {b}_{1} \cdot {b}_{2}} ) \\ but also , Δ θ = 2 π \cdot Δ f \cdot T = \frac{2 π \cdot Δ f}{{f}_{s}} \end{matrix} \qquad ( 8 )$$

When the two different arguments are substituted and the terms are rearranged, the demodulated frequency (f₀) becomes

$$Δ f = {f}_{o} = \frac{Δ θ \cdot {f}_{s}}{2 π} = \frac{{f}_{s}}{2 π} \cdot {tan}^{- 1} ( \frac{{a}_{1} \cdot {b}_{2} - {a}_{2} \cdot {b}_{1}}{{a}_{1} \cdot {a}_{2} + {b}_{1} \cdot {b}_{2}} ) \qquad ( 9 )$$

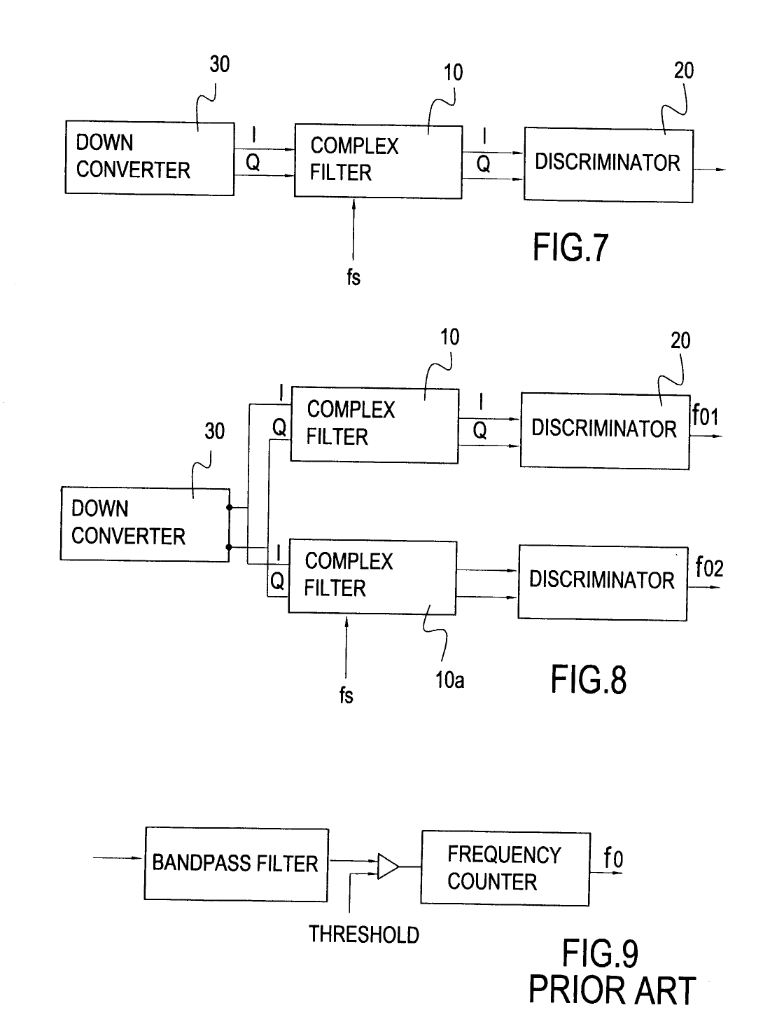

However, due to the use of the inverse trigonometric function tan⁻¹ for frequency computation, the phase angle has to fall within the range −π/2 to π/2, which means the demodulated frequency f₀ cannot be above ¼ of the frequency sampling rate (fₛ). Therefore when the input frequency is higher as shown in FIG. 7, the input of the complex filter (10) must be routed through a down-converter (30) to step down the frequency to an acceptable frequency range.

When the down-converter (30) is added to the circuit, the original modulated frequency has been transformed before being analyzed, so a correction factor (f_{c}) has to be added to the frequency computation by the frequency discriminator (20):

$$that is Δ f = {f}_{o} = \frac{Δ θ \cdot {f}_{s}}{2 π} = \frac{{f}_{s}}{2 π} \cdot {tan}^{- 1} ( \frac{{a}_{1} \cdot {b}_{2} - {a}_{2} \cdot {b}_{1}}{{a}_{1} \cdot {a}_{2} + {b}_{1} \cdot {b}_{2}} ) + {f}_{c} \qquad ( 10 )$$

With reference to FIG. 8, the present invention can also be used for dual frequency analysis, in such case the architecture for the implementation needs to include a pair of complex filters (10, 10a) and a pair of corresponding discriminators (20, 20a) for computing two demodulated frequencies.

The frequency analyzer using the new approach is better than the conventional techniques and has the following advantages:

Low power consumption: By the introduction of a complex function in the invention, the components used in the invention do not have to be high frequency components; whereas analog circuits used in the prior art are accompanied by extremely high frequency operation to obtain the sampling frequency. Therefore, the power consumption of the related circuit can be minimized.

Simplified circuit design: Since only a complex filter and a frequency discriminator are used in the invention, the requirement for frequency computation is relatively easy as compared with the high frequency sampling circuit and high speed A/D converter for conventional circuits.

The foregoing illustration of the current embodiments in the present invention is intended to be illustrative only. Under no circumstances should the scope of the present invention be so restricted.

What is claimed is:

1. A frequency analyzer that comprises:
a complex filter used to sample frequencies; whereby the input frequency is filtered to extract either the positive frequency or negative frequency component;
a frequency discriminator that receives an input from the complex filter; whereby the frequency discriminator can compute the demodulated frequency based on the phase difference between two consecutive demodulated frequencies output from the complex filter using an inverse trigonometric function.

2. A frequency analyzer as claimed in claim 1, wherein the input terminal of the complex filter is connected to a down-converter, such that, when an input frequency above the predetermined frequency limit is put through the down-converter, the frequency can be converted to a suitable range for subsequent sampling.

3. A frequency analyzer as claimed in claim 1, wherein the input frequency after passing through the complex filter becomes two consecutive samples containing signal values x₁, x₂, wherein:
x₁=A₁·e^{j}^{^{θ}}¹=a₁+jb₁
x₂=A₂·e^{j}^{^{θ}}²=a₂+jb₂

4. A frequency analyzer as claimed in claim 3, wherein the frequency discriminator is used to compute the phase difference from two consecutive sampled signals:
$$\begin{matrix}Δ θ = {θ}_{2} - {θ}_{1} = {tan}^{- 1} ( \frac{{a}_{1} \cdot {b}_{2} - {a}_{2} \cdot {b}_{1}}{{a}_{1} \cdot {a}_{2} + {b}_{1} \cdot {b}_{2}} ) \\ also , Δ θ = 2 π \cdot Δ f \cdot T = \frac{2 π \cdot Δ f}{{f}_{s}} \end{matrix}$$
therefore, the demodulated frequency (f0) can be computed using an inverse trigonometric function tan⁻¹:
$$Δ f = {f}_{o} = \frac{Δ θ \cdot {f}_{s}}{2 π} = \frac{{f}_{s}}{2 π} \cdot {tan}^{- 1} ( \frac{{a}_{1} \cdot {b}_{2} - {a}_{2} \cdot {b}_{1}}{{a}_{1} \cdot {a}_{2} + {b}_{1} \cdot {b}_{2}} )$$

5. A frequency analyzer as claimed in claim 1, wherein the sampling frequency to be used has to match the Nyquist sampling rate.

6. A frequency analyzer, which includes:
a pair of complex filters, each of which receives a sampled signal from the same source, which are then passed through a filter selectively keeping either the positive frequency or negative frequency component;
a pair of frequency discriminators, each of which receives the output from the respective complex filter, such that when the complex filter consecutively outputs two sampled signals, the discriminator computes the demodulated frequency with the phase difference from these two output signals, using an inverse trigonometric function.

7. A frequency analyzer as claimed in claim 6, wherein the input terminal of each complex filter is routed through a common down-converter, such that when the input frequency is over a predetermined frequency, the down converter is added to the circuit to convert the signal frequency to a suitable range for taking sample frequencies.

8. A frequency analyzer as claimed in claim 6, wherein the input frequency passing through the complex filter becomes two consecutive sampled signals with respective signal values x₁ and x₂, wherein:
x₁=A₁·e^{j}^{^{θ}}¹=a₁+jb₁
x₂=A₂·e^{j}^{^{θ}}²=a₂+jb₂

9. A frequency analyzer as claimed in claim 8, wherein each frequency discriminator computes the phase difference of two sampled signals as:
$$Δ θ = {θ}_{2} - {θ}_{1} = {tan}^{- 1} ( \frac{{a}_{1} \cdot {b}_{2} - {a}_{2} \cdot {b}_{1}}{{a}_{1} \cdot {a}_{2} + {b}_{1} \cdot {b}_{2}} )$$
$$also , Δ θ = 2 π \cdot Δ f \cdot T = \frac{2 π \cdot Δ f}{{f}_{s}}$$
therefore, each discriminator can use an inverse trigonometric function tan⁻¹ to compute the demodulated frequency (ƒₒ):
$$Δ f = {f}_{o} = \frac{Δθ \cdot {f}_{s}}{2 π} = \frac{{f}_{s}}{2 π} \cdot {tan}^{- 1} ( \frac{{a}_{1} \cdot {b}_{2} - {a}_{2} \cdot {b}_{1}}{{a}_{1} \cdot {a}_{2} + {b}_{1} \cdot {b}_{2}} )$$

10. A frequency analyzer as claimed in claim 6, wherein the sampling rate to be used has to match the Nyquist sampling rate.
